(19) United States
(12) Patent Application Publication
(10) Pub. No.: US 2025/0206535 A1
(43) Pub. Date: Jun. 26, 2025

(54) Article Transport Facility

(71) Applicant: Daifuku Co., Ltd., Osaka-shi (JP)

(72) Inventor: Hidemoto Fukushima, Komaki-shi (JP)

(21) Appl. No.: 18/988,391

(22) Filed: Dec. 19, 2024

(30) Foreign Application Priority Data
Dec. 21, 2023 (JP) 2023-215800

(51) Int. Cl. B65G 1/137

(52) U.S. Cl. CPC B65G 1/1373

(57) ABSTRACT

An article transport facility includes a plurality of movable bodies each configured to move in a movable area. Each of the movable bodies includes a surrounding detection device; and a surrounding information acquisition section configured to acquire surrounding information based on a detection result from the surrounding detection device. A plurality of movable bodies in a predetermined sharing range performs an information sharing process of sharing respective pieces of surrounding information acquired by the plurality of movable bodies. Each of the movable bodies searches for a routes to its destination based on the pieces of surrounding information shared in the information sharing process.

### CROSS-REFERENCE TO RELATED APPLICATION

This application claims priority to Japanese Patent Application No. 2023-215800 filed Dec. 21, 2023, the disclosure of which is hereby incorporated by reference in its entirety.

### BACKGROUND OF THE INVENTION

### 1. Field of the Invention

The present invention relates to an article transport facility.

### 2. Description of Related Art

A distribution center, a factory, and the like, for example, use an article transport facility including a plurality of movable bodies each configured to transport an article. Japanese Unexamined Patent Application Publication No. 2022-45704 discloses an example of such an article transport facility. A plurality of movable bodies (article transport vehicles 3) each transport an article (an article W) to a destination based on a command from a movable-body control device (a facility control device H1). The plurality of movable bodies is communicably connected to the movable-body control device via a communication system (a wireless system).

Each movable body may be configured to determine a route to its destination by search based on destination information received from the movable-body control device, and map information on a map of a movable area. However, the state of the movable area can change every hour, and therefore, a route not necessarily appropriate in view of moving efficiency may be determined when the movable body refers to only the map information.

### SUMMARY OF THE INVENTION

In view of the foregoing, it is desirable to achieve an article transport facility that can improve moving efficiency of a movable body as the whole facility.

An article transport facility according to this disclosure is an article transport facility including: a plurality of movable bodies each configured to travel in a movable area and transport an article; a movable-body control device configured to store control map information on a map of the movable area and to designate a destination to each of the plurality of movable bodies based on the control map information; and a communication system configured to communicably connect the plurality of movable bodies to the movable-body control device. The movable-body control device is configured to transmit destination information on a corresponding destination to each of the plurality of movable bodies via the communication system. Each of the plurality of movable bodies includes: a storage section configured to store movable-body map information on the map of the movable area; a surrounding detection device configured to detect a surrounding state around the surrounding detection device; a surrounding information acquisition section configured to acquire surrounding information on the surrounding state based on a detection result from the surrounding detection device; and a route determination section configured to determine a route to the corresponding destination by search based on the destination information received from the movable-body control device, the movable-body map information, and the surrounding information. The communication system is configured to cause a plurality of movable bodies in a predetermined sharing range to perform an information sharing process of sharing at least some of respective pieces of surrounding information acquired by the plurality of movable bodies. The route determination section of each of the plurality of movable bodies is configured to, in response to acquisition of shared surrounding information derived from another movable body in the information sharing process, search for the route based on the shared surrounding information.

With this configuration, each movable body can precisely search for a route with use of surrounding information acquired based on the detection result from the surrounding detection device, in addition to the movable-body map information. Besides, a plurality of movable bodies in the sharing range shares respective pieces of surrounding information acquired by the plurality of movable bodies based on detection results from their respective surrounding detection devices, so that each of the movable bodies can more precisely search for a route with use of surrounding information derived from another movable body. Thus, the movable body can search for a route in consideration of a state that changes every hour, thereby making it possible to improve moving efficiency of the movable bodies as the whole article transport facility.

Further features and advantages of the technology according to this disclosure will become clearer by the following illustrative and nonlimiting description of embodiments to be described with reference to the drawings.

### BRIEF DESCRIPTION OF THE DRAWINGS

FIG. 1 is a plan view of an article transport facility according to an embodiment;

FIG. 2 is a schematic view of a movable body;

FIG. 3 is a block diagram of a control system;

FIG. 4 is a schematic view of a communication system;

FIG. 5 is a view illustrating an example of surrounding information displayed on a work terminal device;

FIG. 6 is a view illustrating an example of a route of each of a plurality of movable bodies;

FIG. 7 is an explanatory drawing illustrating an example of an information sharing process; and

FIG. 8 is an explanatory drawing illustrating an example of the information sharing process.

### DESCRIPTION OF THE INVENTION

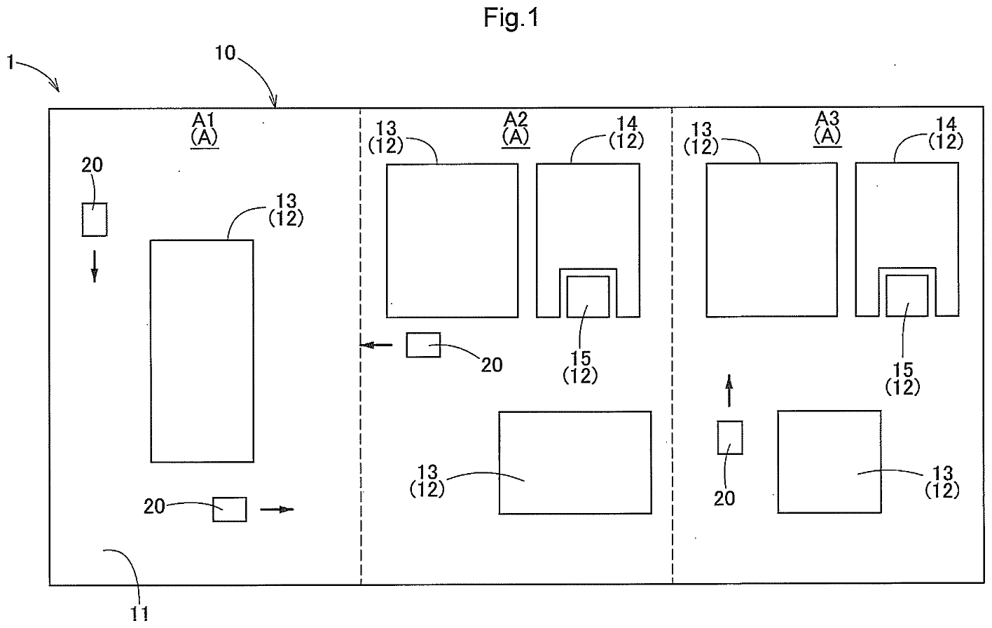

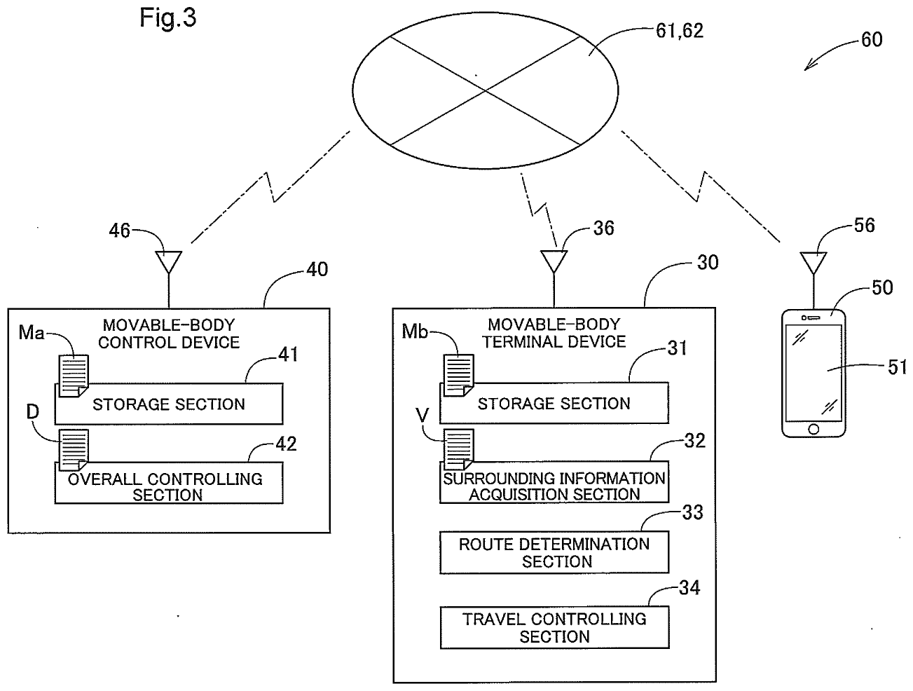

The following will describe an embodiment of an article transport facility with reference to the drawings. An article transport facility 1 of the present embodiment is used to transport an article 7 in a semiconductor factory or the like, for example. As illustrated in FIG. 1, the article transport facility 1 includes a plurality of movable bodies 20 configured to travel on a floor 10. Each of the plurality of movable bodies 20 includes a movable-body terminal device 30. In addition to the movable bodies 20 (the movable-body terminal devices 30), the article transport facility 1 includes a movable-body control device 40, a work terminal device 50, and a communication system 60 as illustrated in FIG. 3. The movable bodies 20 (the movable-body terminal devices 30), the movable-body control device 40, and the work terminal device 50 are communicably connected to each other via the communication system 60.

The floor 10 includes a floor surface 11 and various installed objects 12 provided on the floor surface 11. Examples of the installed object 12 include a storage shelf 13 for storing the article 7, a processing device 14 configured to perform various processes (for example, mask processing, etching, bonding, molding, and the like) on a semiconductor substrate, and so on, for example. The installed objects 12 may further include a mounting table 15 or the like provided along with the processing device 14 and used to receive a transported article 7 and transfer an article 7 to be transported.

Here, examples of the article 7 as a target object to be transported by the movable body 20 include a wafer storage container (so-called FOUP: Front Opening Unified Pod) for storing wafers, a reticle storage container (so-called reticle pod) for storing reticles, and so on, for example.

The movable body 20 travels in an area (hereinafter referred to as an “installed-object absence area”) in which no installed object 12 is put on the floor surface 11 of the floor 10. The movable body 20 travels in an area (a “reduced installed-object absence area”) excluding an area near the installed object 12 (for example, an area distanced from the installed object 12 by a reference distance or less, hereinafter referred to as an “installed-object vicinal area”) from the installed-object absence area on the floor surface 11. In the present embodiment, the reduced installed-object absence area is referred to as a movable area A. The movable area A may be grasped as a single whole area or may be grasped as a plurality of divided areas. The movable area A in the present embodiment includes a first area A1, a second area A2, and a third area A3 arranged sequentially.

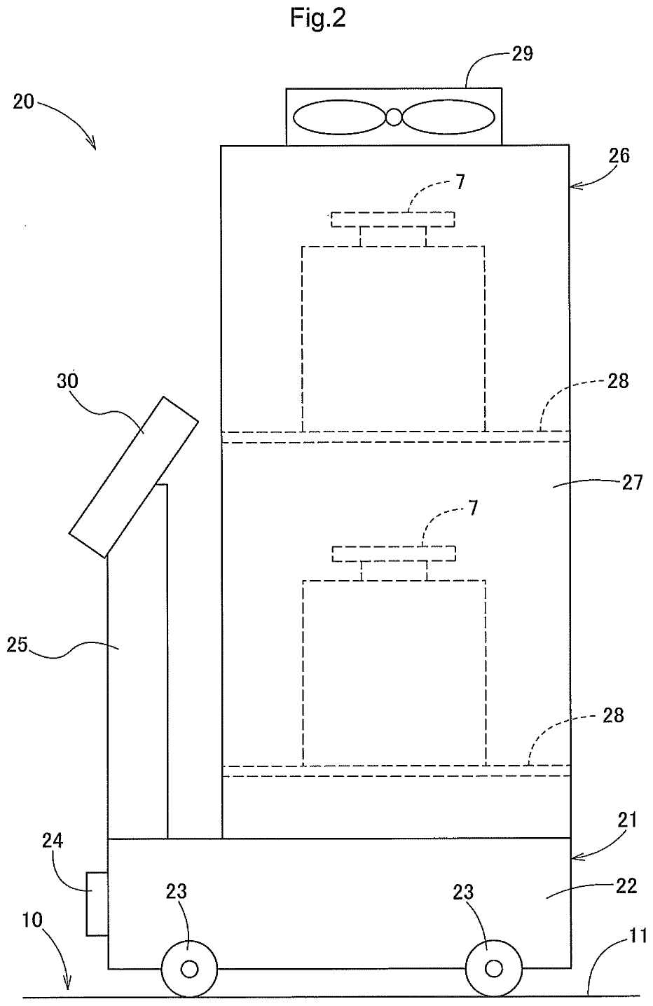

The movable body 20 transports the article 7. As illustrated in FIG. 2, the movable body 20 includes a travel wagon 21 and a clean booth 26. The travel wagon 21 is coupled with the clean booth 26 in such a manner as to move in conjunction with each other. In the present embodiment, the clean booth 26 is put on the travel wagon 21 and fixed thereto, so that the travel wagon 21 and the clean booth 26 move integrally. In the present embodiment, the movable body 20 includes the movable-body terminal device 30.

The travel wagon 21 includes a vehicle main body 22 and a plurality of wheels 23 rotatably supported by the vehicle main body 22. At least one of the plurality of wheels 23 is coupled with a drive motor and functions as a driving wheel. At least one of the plurality of wheels 23 is supported to be rotatable around a shaft along an up-down direction and functions as a steering wheel. The travel wagon 21 includes a surrounding detection device 24. The surrounding detection device 24 is fixed to the vehicle main body 22. FIG. 2 illustrates an example in which a single surrounding detection device 24 is fixed to a front surface of the vehicle main body 22, but a plurality of surrounding detection devices 24 may be separately fixed to an outer surface (including the front surface, a rear surface, lateral surfaces) of the vehicle main body 22 as appropriate.

The surrounding detection device 24 is a device configured to detect its surrounding state (a state around the surrounding detection device 24, eventually, the movable body 20 provided with the surrounding detection device 24). Any detection device can be used as the surrounding detection device 24 without any limitation, provided that the detection device can detect the state around the detection device in some way). Concrete examples of the surrounding detection device 24 include an ultrasonic sensor, an infrared sensor, a laser sensor, LiDAR (Light Detection And Ranging), a microwave sensor, a millimeter wave sensor, a camera, and so on, and some of them may be used together.

The surrounding detection device 24 detects, as its surrounding state, whether or not an object (an obstacle or another movable body 20) is present around the surrounding detection device 24, and the shape, dimension, state, or the like of an object in a case where the object is present around the surrounding detection device 24. Information on a detection result acquired by the surrounding detection device 24 is transmitted to the movable-body terminal device 30 by visible light communication, infrared-ray communication, or the like, for example.

In the present embodiment, a support base 25 is fixed to the travel wagon 21. The movable-body terminal device 30 is attached to the support base 25. The movable-body terminal device 30 may be integrally fixed to the support base 25 or may be detachably attached to the support base 25. In the former case, a microcomputer can be used as the movable-body terminal device 30, for example, and in the latter case, a smart device such as a tablet terminal can be used as the movable-body terminal device 30, for example. The support base 25 may be provided with a receiver configured to receive the information on the detection result which information is transmitted from the surrounding detection device 24.

The clean booth 26 is equipment for forming a space with a high cleanliness in the clean booth 26. The clean booth 26 includes an external wall 27 and a dust removal device 29. The external wall 27 is formed in a rectangular-solid shape and has a side wall extending on four lateral sides of the clean booth 26 and a top wall covering the upper side of the clean booth 26. A storage space for storing the article 7 is formed inside the external wall 27. A support plate 28 for supporting the article 7 from below may be provided inside the external wall 27. In a case where the clean booth 26 includes the support plate 28, a plurality of support plates 28 may be provided.

The dust removal device 29 is provided on the external wall 27. The dust removal device 29 is a device for removing dust from external air taken into the clean booth 26. As the dust removal device 29, a fan filter unit including a fan and a filter (for example, a HEPA filter (High Efficiency Particulate Air filter)) can be used. FIG. 2 illustrates an example in which the dust removal device 29 is provided on the top wall of the external wall 27, but the dust removal device 29 may be provided on a side wall of the external wall 27.

The movable body 20 (more specifically, the movable-body terminal device 30 of the movable body 20) includes a storage section 31, a surrounding information acquisition section 32, a route determination section 33, a travel controlling section 34, and a communication section 36, as illustrated in FIG. 3.

The storage section 31 is a device configured to store various pieces of information. The storage section 31 can be constituted by a RAM (Random Access Memory) included in the movable-body terminal device 30, for example. In the present embodiment, particularly, the storage section 31 stores movable-body map information Mb. The movable-body map information Mb is information indicative of a map of the movable area A in the article transport facility 1. The movable-body map information Mb includes information on position coordinates of each of a plurality of spots in the movable area A, types of the installed objects 12 in a surrounding area, a distance between two adjacent spots, and so on, for example. These are just examples, and the in movable-body map information Mb may include other information.

The surrounding information acquisition section 32 acquires surrounding information V indicative of a state around the surrounding information acquisition section 32 (the movable-body terminal device 30 including the surrounding information acquisition section 32, eventually, the movable body 20 provided with the movable-body terminal device 30). The surrounding information acquisition section 32 acquires the surrounding information V based on a detection result received from the surrounding detection device 24. The surrounding information V acquired by the surrounding information acquisition section 32 may information on the state around the surrounding detection device 24 which information is detected by the surrounding detection device 24 as it is (i.e., raw data) or may be information subjected to given processing (i.e., processing data).

The route determination section 33 determines, by search, a route to a destination to which the article 7 is to be transported. In the present embodiment, the movable-body terminal device 30 receives, from the movable-body control device 40 (described later), destination information D on a destination to which the movable body 20 provided with the movable-body terminal device 30 should be directed. The movable-body terminal device 30 receiving the destination information D determines a route to the destination by search based on the received destination information D, the movable-body map information Mb, and the surrounding information V. The route determination section 33 can search for the route by use of a technique such as a Dijkstra method, for example.

The travel controlling section 34 controls traveling of the movable body 20. The travel controlling section 34 controls the movable body 20 to travel along the route to the destination determined by the route determination section 33.

The communication section 36 communicates with other movable bodies 20 (the movable-body terminal devices 30 of the other movable bodies 20), the movable-body control device 40, and the work terminal device 50. The communication section 36 can use an antenna connectable via Wi-Fi, for example. The communication section 36 constitutes the communication system 60 together with the communication sections 36 of the other movable bodies 20 (their movable-body terminal devices 30), a communication section 46 of the movable-body control device 40, a communication section 56 of the work terminal device 50, and so on. Note that FIG. 3 schematically illustrates the communication section 36 to demonstrate this, but the communication section 36 may be incorporated in the movable-body terminal device 30.

The movable body 20 moves to a destination designated by the destination information D along the route determined by the route determination section 33, under the control of the travel controlling section 34. At this time, the surrounding detection device 24 detects a surrounding state around the movable body 20 in a given cycle, and the surrounding information acquisition section 32 continuously acquires surrounding information V. The movable body 20 performs a necessary deceleration process, temporary stop process, or the like, for example, based on the surrounding information V thus acquired continuously and travels toward the destination along the route. An autonomous mobile robot (AMR) can be used as such a movable body 20, for example.

In a case where the AMR is used as the movable body 20, a plurality of movable bodies 20 and a plurality of operators can collaborate with high security in the article transport facility 1, and therefore, the AMR is preferable. The AMR is also preferable in that the AMR can flexibly cope with layout changes of the installed objects 12 in the article transport facility 1.

The movable-body control device 40 entirely manages the plurality of movable bodies 20. The movable-body control device 40 is a host control device for controlling the movable-body terminal devices 30 of the plurality of movable bodies 20 comprehensively. As the movable-body control device 40, a workstation or the like can be used, for example. The movable-body control device 40 includes a storage section 41, an overall controlling section 42, and a communication section 46, as illustrated in FIG. 3.

The storage section 41 is a device configured to store various pieces of information. The storage section 41 can be constituted by a RAM (Random Access Memory) or a hard disk incorporated in the movable-body control device 40, for example. In the present embodiment, particularly, the storage section 41 stores control map information Ma. The control map information Ma is information on a map of the movable area A in the article transport facility 1. The control map information Ma includes information on position coordinates of each of a plurality of spots in the movable area A, types of the installed objects 12 in a surrounding area, a distance between two adjacent spots, and so on, for example. These are just examples, and the control map information Ma may include other information. The control map information Ma may be the same as the movable-body map information Mb stored in the movable-body terminal device 30 or may be different from the movable-body map information Mb.

The overall controlling section 42 controls the movement of each of the plurality of movable bodies 20 comprehensively. In the present embodiment, the overall controlling section 42 designates a destination to each of the plurality of movable bodies 20 based on the control map information Ma stored in the storage section 41. The destination of the movable body 20 may be a position of the storage shelf 13 or the mounting table 15 from which the movable body 20 should receive the article 7, a position of the storage shelf 13 or the mounting table 15 to which the movable body 20 should deliver the article 7, or the like, for example. The overall controlling section 42 generates destination information D on a destination for each of the plurality of movable bodies 20.

The destination information D generated by the overall controlling section 42 is transmitted via the communication section 46. The communication section 46 communicates with the plurality of movable bodies 20 (the movable-body terminal devices 30 of the plurality of movable bodies 20) and the work terminal device 50. The communication section 46 can use an antenna connectable via Wi-Fi, for example. The communication section 46 may be incorporated in the movable-body control device 40. The communication sections 46 constitutes the communication system 60 together with the communication sections 36 of the plurality of movable bodies 20 (the movable-body terminal devices 30), the communication section 56 of the work terminal device 50, and so on.

The work terminal device 50 is a terminal device carried by an operator working in the article transport facility 1. A smart device such as a smartphone or a tablet terminal can be used as the work terminal device 50, for example. The work terminal device 50 includes a display section 51 and the communication section 56.

The display section 51 is a device configured to display various pieces of information. The display section 51 is constituted by a liquid crystal display or an organic EL display, for example. The display section 51 may be integrated with a touch panel so that the display section 51 is also used as an input section. The display section 51 can display information received via the communication section 56.

The communication section 56 communicates with the plurality of movable bodies 20 (the movable-body terminal devices 30 of the plurality of movable bodies 20) and the movable-body control device 40. The communication section 56 can use an antenna connectable via Wi-Fi, for example. The communication section 56 may be incorporated in the work terminal device 50. The communication section 56 constitutes the communication system 60 together with the communication sections 36 of the plurality of movable bodies 20 (the movable-body terminal devices 30), the communication section 46 of the movable-body control device 40, and so on.

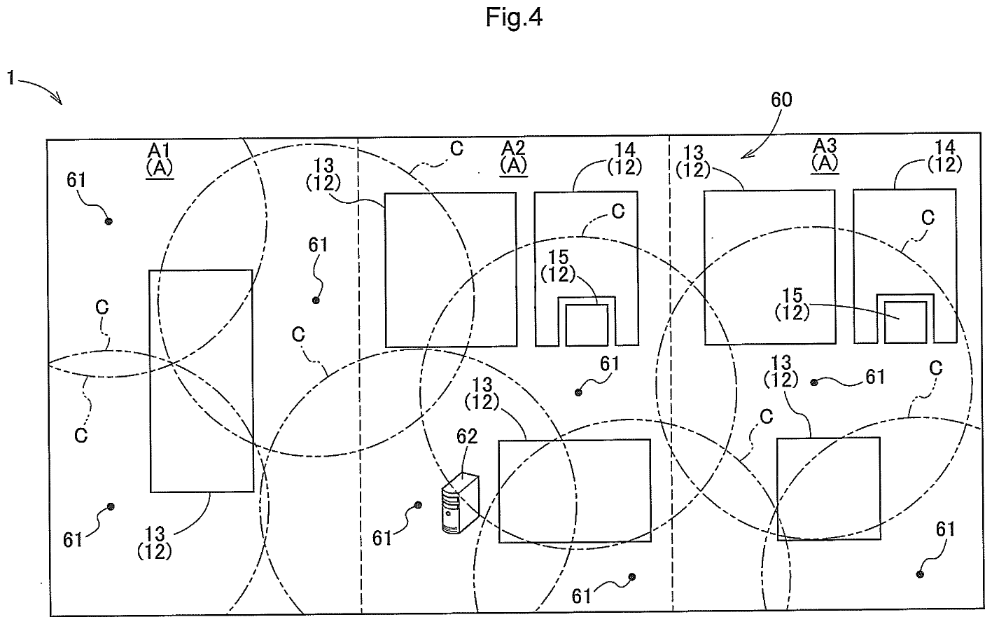

The communication system 60 connects the plurality of movable bodies 20 (the movable-body terminal devices 30), the movable-body control device 40, and the work terminal device 50 such that they are communicable with each other. The communication system 60 of the present embodiment connects the plurality of movable bodies 20 (the movable-body terminal devices 30), the movable-body control device 40, and the work terminal device 50 such that they are communicable with each other by radio communication (for example, Wi-Fi communication in conformity with IEEE802.11 standard). As illustrated in FIG. 4, the communication system 60 includes a plurality of radio transmission and reception sections 61 and a relay processing device 62.

The radio transmission and reception sections 61 are provided at a plurality of places in the movable area A in the article transport facility 1. The radio transmission and reception section 61 is equipment for transmitting and receiving radio electric waves (Wi-Fi electric waves) and corresponds to a so-called access point. The radio transmission and reception section 61 may have both a function as the access point and a function as a router. A communicable range C is set for each of the plurality of radio transmission and reception sections 61. The communicable range C of each radio transmission and reception section 61 is generally a range within a predetermined distance around the position of the radio transmission and reception section 61. The plurality of radio transmission and reception sections 61 is provided to cover large part of (preferably, the whole) movable area A by their respective communicable ranges C.

The relay processing device 62 is communicably connected to the plurality of radio transmission and reception sections 61. The relay processing device 62 of the present embodiment is communicably connected to some radio transmission and reception sections 61 among all the radio transmission and reception sections 61 provided for the article transport facility 1. In the present embodiment, one relay processing device 62 is provided for each divided area (in the present example, a first area A1, a second area A2, and a third area A3) of the movable area A. The relay processing device 62 in each divided area is communicably connected to a plurality of radio transmission and reception sections 61 within the divided area (in FIG. 4, only the relay processing device 62 in the second area A2 is illustrated, but the first area A1 and the third area A3 are also provided with respective relay processing devices 62).

The relay processing device 62 is a processing device for performing some data-processing in a peripheral portion of the network, separately from the movable-body control device 40, and corresponds to a co-called edge computer. The relay processing device 62 takes a central role of an information sharing process performed by the communication system 60 in the article transport facility 1 of the present embodiment.

As described above, each movable body 20 moves (travels) while the movable body 20 acquires surrounding information V via the surrounding information acquisition section 32 of the movable-body terminal device 30. In the information sharing process performed by the communication system 60, a plurality of movable bodies 20 in a predetermined sharing range S shares at least some of respective pieces of surrounding information V acquired by the plurality of movable bodies 20.

The sharing range S as a position condition for the plurality of movable bodies 20 to perform the information sharing process is set based on the communicable range C of each radio transmission and reception section 61. In the present embodiment, the sharing range S is set to the communicable range C of each radio transmission and reception section 61. In this case, a plurality of movable bodies 20 in the communicable range C of a given single radio transmission and reception section 61 shares at least some of respective pieces of surrounding information V acquired by the plurality of movable bodies 20, and this process is performed in the communicable range C of each of the plurality of radio transmission and reception sections 61.

In the information sharing process, a movable body 20 present in a given sharing range S (a given communicable range C) transmits surrounding information V to the radio transmission and reception section 61 in the sharing range S (the communicable range C). The radio transmission and reception section 61 receiving the surrounding information V transfers the surrounding information V to the relay processing device 62 provided in the same divided area as the radio transmission and reception section 61. The relay processing device 62 stores the received surrounding information V in a storage section (a built-in RAM, hard disk, or the like) of the relay processing device 62. The relay processing device 62 transmits pieces of surrounding information V stored and accumulated in the storage section to another movable body 20 in the same sharing range S (communicable range C). Thus, the plurality of movable bodies 20 shares the pieces of surrounding information V.

Note that the plurality of movable bodies 20 sharing the surrounding information V by the information sharing process may be present in the sharing range S (the communicable range C) at the same timing or may be present in the sharing range S (the communicable range C) at different timings. Particularly, in the present embodiment, since the relay processing device 62 is provided, a plurality of movable bodies 20 present in the sharing range S (the communicable range C) at different timings can share the surrounding information V. That is, in the information sharing process of the present embodiment, the surrounding information V stored in the relay processing device 62 is shared with another movable body 20 entering the sharing range S afterwards.

In the present embodiment, in the information sharing process, at least part of surrounding information V acquired by a given movable body 20 is also shared with the work terminal device 50 in the sharing range S. As described above, the relay processing device 62 stores, in the storage section, the surrounding information V received from the given movable body 20. The relay processing device 62 transmits pieces of surrounding information V stored and accumulated in the storage section to the work terminal device 50 in the same sharing range S (communicable range C), so that the pieces of surrounding information V are also shared with the work terminal device 50.

Information to be shared in the information sharing process may be all or only some of pieces of surrounding information V acquired by the movable bodies 20. Even in the latter case, it is preferable that surrounding information V to be shared include at least information that influences movements of the movable bodies 20. Here, examples of the information that influences the movements of the movable bodies 20 include information indicative of the movable area A being under construction, information indicative of bumps in the movable area A, information indicative of obstacles (including another movable body 20 that cannot move due to malfunction or the like), and so on, for example. It is preferable that these pieces of information be each linked with positional information on a corresponding spot.

The information that influences the movements of the movable bodies 20 is not limited to information that actually influences the movements and may include information that does not influence the movements at present but is expected to possibly influence the movements in the near future. Such future prediction information may be information indicating that there is a movable body 20 acting unnaturally in the movable area A, for example.

The route determination section 33 of the movable body 20 acquiring surrounding information V derived from another movable body 20 by the information sharing process searches for a route to its destination based on the surrounding information V thus acquired. That is, the route determination section 33 of the movable body 20 searches for the route based on the destination information D, the movable-body map information Mb, the surrounding information V acquired by the movable body 20 itself, and the surrounding information V derived from the another movable body 20 and acquired by the information sharing process. Note that, when the route has not been determined yet at this point, the route determination section 33 newly searches for a route to the destination and determines the route. In the meantime, when the route has been already determined at this point, the route determination section 33 searches for a route to the destination again. As such, searching (new searching or re-searching) of the route can be precisely performed by effectively utilizing the surrounding information V derived from the another movable body 20.

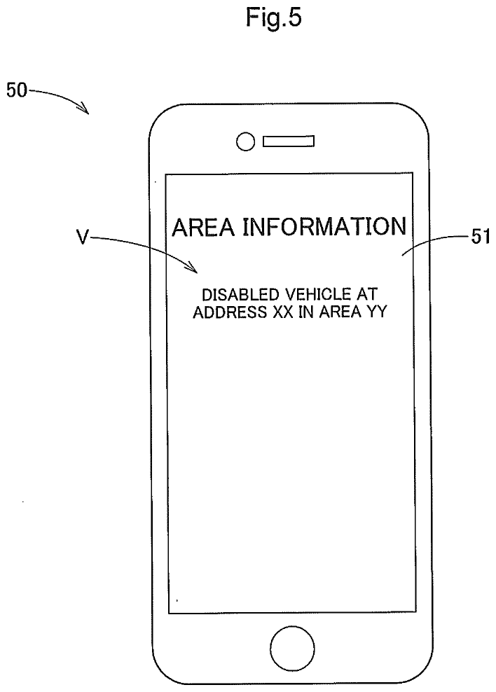

The work terminal device 50 acquiring surrounding information V shared by the information sharing process displays the surrounding information V thus shared on the display section 51. For example, as illustrated in FIG. 5, the work terminal device 50 displays the surrounding information V on the display section 51 in the form of a text. The work terminal device 50 may display the surrounding information V on the display section 51 in the form of an image. The work terminal device 50 may also output the surrounding information V from a speaker as voice data.

The surrounding information V to be shared may also include information that does not influence the movements of the movable bodies 20 other than the information that influences the movements of the movable bodies 20. Here, examples of the information that does not influence the movements of the movable bodies 20 include information related to construction or an obstacle outside the movable area A, environmental information (information on temperature, humidity, or the like) in the article transport facility 1, and so on.

In the information sharing process, since the information that does not influence the movements of the movable bodies 20, among pieces of surrounding information V, is shared, various pieces of information can be transmitted to the operator, for example, and this can improve convenience for the operator. Accordingly, in a case where information including the information that does not influence the movements of the movable bodies 20 is shared, it is preferable that respective pieces of surrounding information V of the movable bodies 20 be shared not only between the movable bodies 20 but be also shared with the work terminal device 50 in the same sharing range S (communicable range C).

In the meantime, a configuration in which the information that does not influence the movements of the movable bodies 20, among pieces of surrounding information V, is not shared in the information sharing process has such an advantage that a load to the communication system 60 can be reduced. On this account, information to be shared may be changed depending on with what the information is shared, e.g., only the information that influences the movements of the movable bodies 20, among the pieces of surrounding information V, may be shared between the movable bodies 20, and all the pieces of surrounding information V may be shared with the work terminal device 50.

It is preferable that a plurality of movable bodies 20 sharing respective pieces of surrounding information V by the information sharing process move on respective routes toward different directions. In a case where a plurality of movable bodies 20 moving on respective routes toward different directions shares respective pieces of surrounding information V, the respective pieces of surrounding information V can supplement each other, so that the movable bodies 20 can precisely search (newly search or search again) for respective routes. Directions of respective routes of the plurality of movable bodies 20 preferably form an angle of 90° or more, and more preferably reverse to each other.

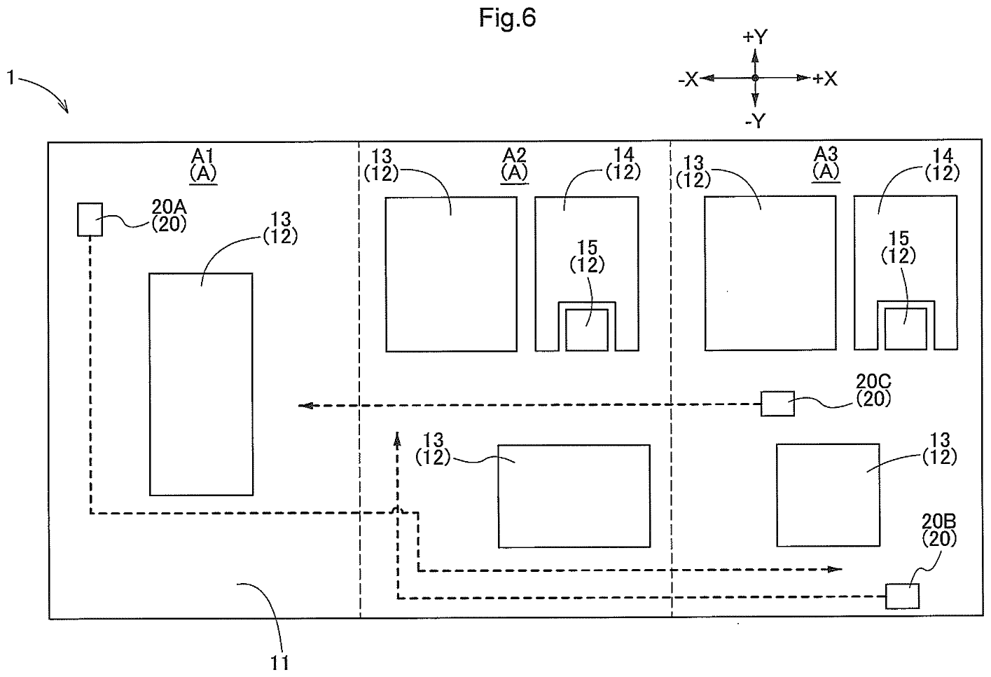

With reference to FIGS. 6 to 8, the following describes more details of an example of the information sharing process. In this example, three movable bodies 20 move along respective routes indicated by dotted arrows in FIG. 6. Note that, for convenience of description, the three movable bodies 20 are distinguished from each other with use of reference numerals “20A,” “20B,” and “20C.”

As illustrated in FIG. 6, generally, the movable body 20A moves in a negative Y-direction in the first area A1, then changes its direction to a positive X-direction, and moves in the positive X-direction from the first area A1 to the third area A3. Generally, the movable body 20B moves in a negative X-direction from the third area A3 to the second area A2, then changes its direction to a positive Y-direction, and moves in the positive Y-direction in the second area A2. Generally, the movable body 20C moves in a portion closer to the positive Y-direction than the movable body 20B and moves in the negative X-direction from the third area A3 to the first area A1.

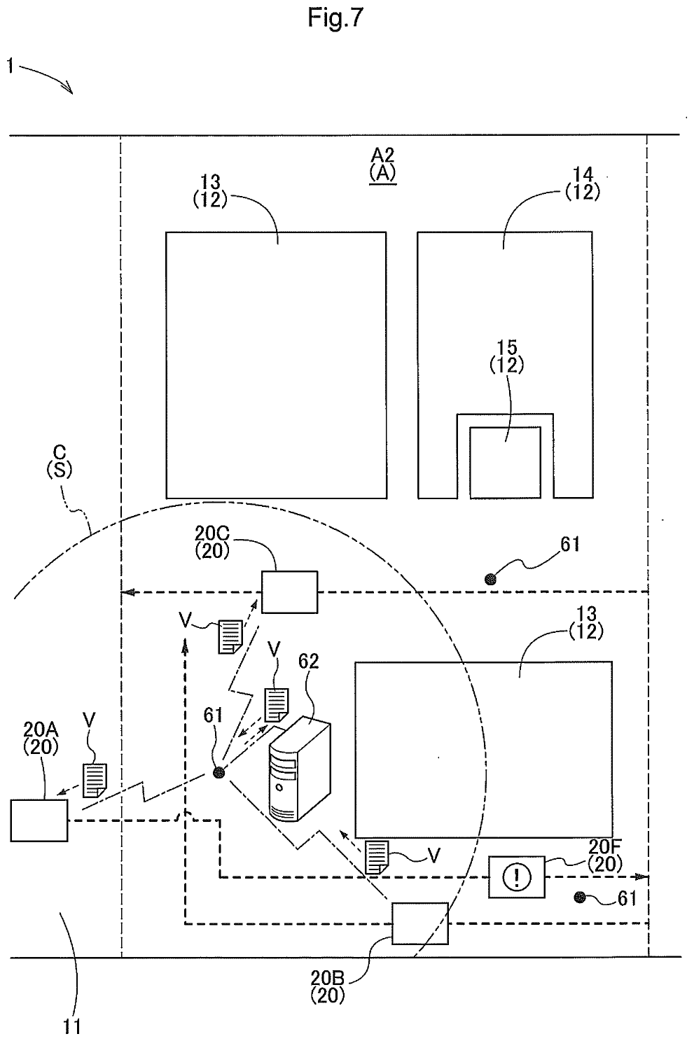

At this time, as illustrated in FIG. 7, there is another movable body 20 (indicated by “20F” in FIG. 7), which becomes immovable due to a malfunction, near a route of the movable body 20B in the second area A2. When the movable body 20B passes by the movable body 20F, the movable body 20B generates surrounding information V indicating that an obstacle (the disabled movable body 20F) is present at its corresponding position. The surrounding information V thus generated is stored in the storage section 31 of the movable-body terminal device 30 of the movable body 20B.

After that, when the movable body 20B enters the communicable range C of a new radio transmission and reception section 61 in its destination, the movable body 20B transmits, to a corresponding relay processing device 62, the surrounding information V indicating the presence of the obstacle (the disabled movable body 20F) which surrounding information V is acquired earlier. The relay processing device 62 stores, in its storage section, the surrounding information V derived from the movable body 20B and received from the movable body 20B. In addition, the relay processing device 62 transmits surrounding information V stored therein to another movable body 20 (in this example, the movable bodies 20A, 20C) in the communicable range C (i.e., the sharing range S) of the same radio transmission and reception section 61 at that point.

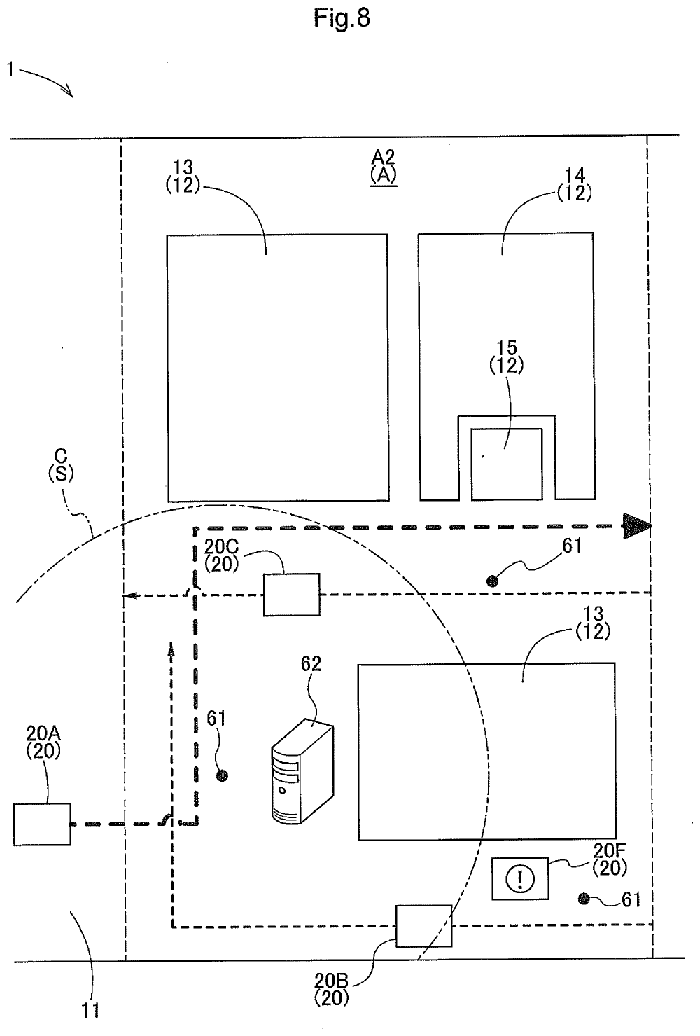

The movable body 20A searches again for a route to its destination based on received surrounding information V (herein, particularly including at least the surrounding information V derived from the movable body 20B). The surrounding information V derived from the movable body 20B includes information indicating the presence of the obstacle (the disabled movable body 20F) in an area for which the movable body 20A is heading, therefore a passage cost of a route passing by the position of the obstacle becomes larger. As a result, the possibility that the movable body 20A determines a new route (indicated by a bold dotted arrow in FIG. 8) detouring around the obstacle (the disabled movable body 20F) by route re-search increases. This accordingly makes it possible to reduce the possibility that a jam occurs at the spot where the obstacle (the disabled movable body 20F) is present, thereby making it possible to improve moving efficiency of the movable body 20 as the whole article transport facility 1.

Note that the movable body 20C also receives the same surrounding information V. However, the position of the obstacle (the disabled movable body 20F) is not an area for which the movable body 20C is heading, and therefore, even when the movable body 20C performs route re-search, the route of the movable body 20C is not changed.

In a case where there is an operator who has the work terminal device 50 in the communicable range C (the sharing range S) of the same radio transmission and reception section 61, the relay processing device 62 also transmits the stored surrounding information V to the work terminal device 50. The work terminal device 50 receiving the surrounding information V displays it on the display section 51 (see FIG. 5, for example). When information related to the disabled movable body 20F is displayed on the display section 51 of the work terminal device 50 like this example, the operator who sees the information can head for the disabled movable body 20 to deal with the malfunction as soon as possible. By providing the operator with various pieces of information, it is possible to improve convenience for the operator.

### Other Embodiments

(1) The above embodiment has described the configuration in which, in the information sharing process, a plurality of movable bodies 20 in the sharing range S shares respective pieces of surrounding information V with each other and also shares the respective pieces of surrounding information V with the work terminal device 50 in the same sharing range S. However, the present invention is not limited to such a configuration, and in the information sharing process, only the plurality of movable bodies 20 in the sharing range S may share the respective pieces of surrounding information V with each other. Alternatively, in the information sharing process, surrounding information V acquired by a given movable body 20 may be shared with only the work terminal device 50 in the same sharing range S.

(2) The above embodiment has been described mainly assuming the configuration in which the movable body 20 communicates with the relay processing device 62 via the radio transmission and reception section 61. However, the present invention is not limited to such a configuration, and the movable body 20 may directly communicate with the relay processing device 62. For example, at the time when the movable body 20 passes in the vicinity of the relay processing device 62, the movable body 20 may communicate with the relay processing device 62 by street-pass communication. The street-pass communication between the movable body 20 and the relay processing device 62 can be performed when the distance between the movable body 20 and the relay processing device 62 is equal to or less than a reference distance. In this case, the reference distance can be set to a distance N times (N is an integer equal to or less than 3, for example) the width of the movable body 20, or the like.

(3) The above embodiment has described, as an example, the configuration in which information sharing between a plurality of movable bodies 20 is performed via the radio transmission and reception section 61 and the relay processing device 62. However, the present invention is not limited to such a configuration, and the plurality of movable bodies 20 may directly communicate with each other to share respective pieces of surrounding information V with each other, for example. The direct communication between the plurality of movable bodies 20 should be performed when they pass each other, for example. The street-pass communication between the plurality of movable bodies 20 can be performed when the distance between the plurality of movable bodies 20 is equal to or less than a reference distance. In this case, the reference distance can be set to a distance M times (M is an integer equal to or less than 3, for example) the width of the movable body 20, or the like.

(4) The above embodiment has described, as an example, the configuration in which the sharing range S in which the information sharing process is performed is set to the communicable range C of each radio transmission and reception section 61. However, the present invention is not limited to such a configuration, and the sharing range S may be set to a range including a plurality of communicable ranges C of a plurality of radio transmission and reception sections 61, for example. The sharing range S may be set to the whole movable area A or a divided area (the first area A1, the second area A2, or the third area A3). Alternatively, the sharing range S may be set to a range smaller than the communicable range C of any of the radio transmission and reception sections 61.

(5) The above embodiment has been described mainly assuming the configuration in which the overall controlling section 42 of the movable-body control device 40 determines a destination for each of the plurality of movable bodies 20 and designates the destination based on the determination. However, the present invention is not limited to such a configuration. A host control system higher than the movable-body control device 40 may be provided, and the overall controlling section 42 of the movable-body control device 40 may designate the destination based on a command from the host control system.

(6) The above embodiment has described, as an example, the configuration in which the travel wagon 21 and the clean booth 26 constituting the movable body 20 move integrally with the clean booth 26 being fixed onto the travel wagon 21. However, the present invention is not limited to such a configuration, and the travel wagon 21 may move in such a manner as to pull the clean booth 26 equipped with casters, for example. As such, the travel wagon 21 and the clean booth 26 constituting the movable body 20 may move in a line.

(7) The above embodiment has described, as an example, the configuration in which the movable body 20 is a movable body configured to travel on the floor surface 11. However, the present invention is not limited to such a configuration, and the movable body 20 may be a flying body (for example, a drone) configured to fly in the space of the article transport facility 1. In this case, in a case where there is a space where the flying body can fly above the installed object 12 on the floor surface 11, the movable area A is not limited to the installed-object absence area on the floor surface 11, and an area where the installed object 12 is present can be also included in the movable area A.

(8) The configurations described in the embodiments (the above embodiment and other embodiments; the same applies hereinafter) can be applied in combination with configurations of other embodiments as long as no inconsistency occurs. In terms of the other configurations, the embodiments disclosed in the present specification are just examples in all respects, and various modifications can be made within a range that does not deviate from the gist of this disclosure.

### Overview of Embodiment

When the above descriptions are summarized, the article transport facility according to this disclosure preferably has the following configurations.

An article transport facility includes: a plurality of movable bodies each configured to travel in a movable area and transport an article; a movable-body control device configured to store control map information on a map of the movable area and to designate a destination to each of the plurality of movable bodies based on the control map information; and a communication system configured to communicably connect the plurality of movable bodies to the movable-body control device. The movable-body control device is configured to transmit destination information on a corresponding destination to each of the plurality of movable bodies via the communication system. Each of the plurality of movable bodies includes: a storage section configured to store movable-body map information on the map of the movable area; a surrounding detection device configured to detect a surrounding state around the surrounding detection device; a surrounding information acquisition section configured to acquire surrounding information on the surrounding state based on a detection result from the surrounding detection device; and a route determination section configured to determine a route to the corresponding destination by search based on the destination information received from the movable-body control device, the movable-body map information, and the surrounding information. The communication system is configured to cause a plurality of movable bodies in a predetermined sharing range to perform an information sharing process of sharing at least some of respective pieces of surrounding information acquired by the plurality of movable bodies. The route determination section of each of the plurality of movable bodies is configured to, in response to acquisition of shared surrounding information derived from another movable body in the information sharing process, search for the route based on the shared surrounding information.

With this configuration, each movable body can precisely search for a route with use of surrounding information acquired based on the detection result from the surrounding detection device, in addition to the movable-body map information. Besides, a plurality of movable bodies in the sharing range shares respective pieces of surrounding information acquired by the plurality of movable bodies based on detection results from their respective surrounding detection devices, so that each of the movable bodies can more precisely search for a route with use of surrounding information derived from another movable body. Thus, the movable body can search for a route in consideration of a state that changes every hour, thereby making it possible to improve moving efficiency of the movable bodies as the whole article transport facility.

As one aspect, the communication system may include: a plurality of radio transmission and reception sections provided for respective portions of the movable area; and a relay processing device connected to the plurality of radio transmission and reception sections. The sharing range may be set to a communicable range of each of the plurality of radio transmission and reception sections. The relay processing device may store surrounding information shared in the information sharing process. The relay processing device may allow the surrounding information thus stored to be shared with another movable body entering the sharing range after the information sharing process is performed.

With this configuration, since the relay processing device stores surrounding information shared in the information sharing process, the surrounding information can be also shared with a movable body entering the sharing range with a time difference. Thus, more movable bodies can precisely search for their routes, thereby making it possible to improve moving efficiency of the movable bodies as the whole article transport facility.

As one aspect, the communication system may be configured to cause at least a plurality of movable bodies moving on respective routes in respective directions reverse to each other to perform the information sharing process.

With this configuration, each of the movable bodies can acquire surrounding information on an area toward which each of the movable bodies is heading, from another movable body passing by each of the movable bodies. Hereby, the movable body can precisely search for a route in consideration of a surrounding state of a future route of the movable body.

As one aspect, the information sharing process may be performed to share at least information that influences movements of the plurality of movable bodies, from among the respective pieces of surrounding information acquired by the plurality of movable bodies.

With this configuration, each of the movable bodies can precisely search for a route appropriately in consideration of an event that influences its movement (or an even that possibly influences the movement).

As one aspect, the article transport facility may further include a work terminal device including a display section and carried by an operator. The communication system may cause at least part of surrounding information acquired by a given movable body to be also shared with the work terminal device in the sharing range in the information sharing process. The work terminal device may be configured to, in response to acquisition of the at least part of surrounding information shared in the information sharing process, display the at least part of surrounding information on the display section.

In this configuration, when surrounding information acquired by each of the movable bodies based on a detection result from its surrounding detection device is shared with the work terminal device in the sharing range, the work terminal device displays the surrounding information thus shared on the display section of the work terminal device, so that the operator can be informed of the surrounding information thus shared. This accordingly makes it possible to improve moving efficiency of the movable bodies as the whole article transport facility and to also improve convenience for the operator who performs various works in the article transport facility.

Another article transport facility according to this disclosure preferably has the following configurations.

That is, the article transport facility includes: a plurality of movable bodies each configured to travel in a movable area and transport an article; a movable-body control device configured to store control map information on a map of the movable area and to designate a destination to each of the plurality of movable bodies based on the control map information; a work terminal device including a display section and carried by an operator; and a communication system configured to communicably connect the plurality of movable bodies, the movable-body control device, and the work terminal device to each other. Each of the plurality of movable bodies includes: a surrounding detection device configured to detect a surrounding state around the surrounding detection device; and a surrounding information acquisition section configured to acquire surrounding information on the surrounding state based on a detection result from the surrounding detection device. The communication system is configured to cause a given movable body and the work terminal device in a predetermined sharing range to perform an information sharing process of sharing at least part of surrounding information acquired by the given movable body. The work terminal device is configured to, in response to acquisition of the at least part of the surrounding information thus shared in the information sharing process, display the at least part of the surrounding information on the display section.

In this configuration, when surrounding information acquired by each of the movable bodies based on a detection result from its surrounding detection device is shared with the work terminal device in the sharing range, the work terminal device displays the surrounding information thus shared on the display section of the work terminal device, so that the operator can be informed of the surrounding information. This accordingly makes it possible to improve convenience for the operator who performs various works in the article transport facility.

The article transport facility according to this disclosure should be able to achieve at least one of the above effects.

What is claimed is:

1. An article transport facility, comprising:
a plurality of movable bodies each configured to travel in a movable area and transport an article;
a movable-body control device configured to store control map information on a map of the movable area and to designate a destination to each of the plurality of movable bodies based on the control map information; and
a communication system configured to communicably connect the plurality of movable bodies to the movable-body control device, and
wherein:
the movable-body control device is configured to transmit destination information on a corresponding destination to each of the plurality of movable bodies via the communication system,
each of the plurality of movable bodies comprises:
a storage section configured to store movable-body map information on the map of the movable area;
a surrounding detection device configured to detect a surrounding state around the surrounding detection device;
a surrounding information acquisition section configured to acquire surrounding information on the surrounding state based on a detection result from the surrounding detection device; and
a route determination section configured to determine a route to the corresponding destination by search based on the destination information received from the movable-body control device, the movable-body map information, and the surrounding information,
the communication system is configured to cause a plurality of movable bodies in a predetermined sharing range to perform an information sharing process of sharing at least some of respective pieces of surrounding information acquired by the plurality of movable bodies,
the route determination section of each of the plurality of movable bodies is configured to, in response to acquisition of shared surrounding information derived from another movable body in the information sharing process, search for the route based on the shared surrounding information.

2. The article transport facility according to claim 1, wherein:
the communication system comprises:
a plurality of radio transmission and reception sections provided for respective portions of the movable area; and
a relay processing device connected to the plurality of radio transmission and reception sections,
the sharing range is set to a communicable range of each of the plurality of radio transmission and reception sections,
the relay processing device stores surrounding information shared in the information sharing process, and
the relay processing device allows the surrounding information thus stored to be shared with another movable body entering the sharing range after the information sharing process is performed.

3. The article transport facility according to claim 1, wherein:
the communication system is configured to cause at least a plurality of movable bodies moving on respective routes in respective directions reverse to each other to perform the information sharing process.

4. The article transport facility according to claim 1, wherein:
the information sharing process is performed to share at least information that influences movements of the plurality of movable bodies, from among the respective pieces of surrounding information acquired by the plurality of movable bodies.

5. The article transport facility according to claim 1, further comprising:
a work terminal device comprising a display section and carried by an operator, and
wherein:
the communication system causes at least part of surrounding information acquired by a given movable body to be also shared with the work terminal device in the sharing range in the information sharing process, and
the work terminal device is configured to, in response to acquisition of the at least part of surrounding information shared in the information sharing process, display the at least part of surrounding information on the display section.

6. An article transport facility, comprising:
a plurality of movable bodies each configured to travel in a movable area and transport an article;
a movable-body control device configured to store control map information on a map of the movable area and to designate a destination to each of the plurality of movable bodies based on the control map information;
a work terminal device comprising a display section and carried by an operator; and
a communication system configured to communicably connect the plurality of movable bodies, the movable-body control device, and the work terminal device to each other, and
wherein:
each of the plurality of movable bodies comprises:
a surrounding detection device configured to detect a surrounding state around the surrounding detection device; and
a surrounding information acquisition section configured to acquire surrounding information on the surrounding state based on a detection result from the surrounding detection device,
the communication system is configured to cause a given movable body and the work terminal device in a predetermined sharing range to perform an information sharing process of sharing at least part of surrounding information acquired by the given movable body,
the work terminal device is configured to, in response to acquisition of the at least part of the surrounding information thus shared in the information sharing process, display the at least part of the surrounding information on the display section.
